(19) United States
(12) Patent Application Publication
(10) Pub. No.: US 2019/0206754 A1
(43) Pub. Date: Jul. 4, 2019

(54) ELECTRONIC PACKAGE AND METHOD OF MANUFACTURING THE SAME

(71) Applicant: PHOENIX & CORPORATION, Grand Cayman (KY)

(72) Inventors: Che-Wei Hsu, Hsinchu County (TW); Shih-Ping Hsu, Hsinchu County (TW); Chu-Chin Hu, Hsinchu County (TW)

(21) Appl. No.: 15/924,605

(22) Filed: Mar. 19, 2018

(30) Foreign Application Priority Data
Dec. 28, 2017 (TW) 106146246

(51) Int. Cl. H01L 23/31; H01L 23/00; H01L 23/29; H01L 23/538; H01L 21/48

(52) U.S. Cl. CPC H01L 23/3128; G06K 9/00013; H01L 23/295; H01L 23/5384; H01L 24/19; H01L 21/486; H01L 23/5389; H01L 23/5386; H01L 2224/215; H01L 2224/0231; H01L 2224/02379; H01L 2224/211; H01L 2224/13024; H01L 2924/01029; H01L 24/11; H01L 24/16; H01L 2224/16225; H01L 24/20

(57) ABSTRACT

The disclosure provides an electronic package including an encapsulating layer, an electronic component embedded in the encapsulating layer, a plurality of conductors disposed through the encapsulating layer, and a circuit layer disposed on the encapsulating layer and electrically connected to the conductors, thereby reducing manufacturing complexity by disposing the conductors through the encapsulating layer to save costs. The disclosure further provides a method for manufacturing the electronic package as described above.

### BACKGROUND

### 1. Technical Field

The present disclosure relates to sensing devices, and, more particularly, to an electronic package including a sensing chip and a method for manufacturing the same.

### 2. Description of Related Art

High-end electronic products are being developed with high integration in mind for more compact and lightweight electronic products. With more consumers paying attention to their privacy, many high-end electronic products are equipped with user recognition systems to increase the security of data stored therein. Driven by consumer demands, the research and development of such recognition systems have become one of the main focuses in the electronic industry.

Current biometric devices, such as fingerprint sensors or complementary metal-oxide-semiconductor (CMOS) image sensors, based on their scanning methods, can be divided into optical biometric devices that scan images and silicon-based biometric devices that detects minute charges.

FIG. 1A is a cross-sectional view of a conventional optical biometric package structure 1a. The conventional package structure 1a includes a package substrate 10 having a plurality of electrical connection pads 100, a sensing chip 11 disposed on the package substrate 10 having a sensing area A and a plurality of electrode pads 110, an encapsulant 13 encapsulating the sensing chip 11, and a transparent member 14 disposed above the sensing area A. The package substrate 10 can be connected to a circuit board (not shown) via solder bumps (not shown) at the bottom thereof, and the electrical connection pads 100 on the package substrate 10 are electrically connected with the electrode pads 110 of the sensing chip 11 through a plurality of wires 12. The transparent member 14 has an indentation 140 for accommodating the encapsulant 13 and the package substrate 10.

However, in the conventional package structure 1a, the sensing chip 11 is electrically connected with the package substrate 10 by wire bonding. This makes it difficult to reduce the height of the encapsulant 13 as the arc height of the wires 12 needs to be taken into account. As a result, the height L of the encapsulant 13 and the package substrate 10 and in turn the depth H of the indentation 140 of the transparent member 14 cannot be effectively reduced. The resulting electronic products formed in subsequent processes therefore fail to meet the requirements for compact and lightweight electronic products.

Although the periphery area of the sensing chip 11 where electrode pads 110 are located can be etched away to form recesses B for reducing the arc height of the wires 12, the reduction in height is limited, and the manufacturing costs are significantly higher since etching of the sensing chip 11 is required to obtain the recesses B.

Therefore, optical biometric devices without wire bonding have been developed. As seen in FIG. 1B, a conventional package structure 1b employs a so-called through-silicon via (TSV) manufacturing process, in which a plurality of conductive pillars 111 penetrating the sensing chip 11 are formed corresponding to the locations of the electrode pads 110 of the sensing chip 11. The electrical connection pads 100 of the package substrate 10 are electrically connected with the electrode pads 110 of the sensing chip 11 by these conductive pillars 111. This omits the need to encapsulate the wires 12 in the encapsulant 13, thereby lowering the height of the encapsulant 13 and the package substrate 10 and in turn the depth of the indentation 140 of the transparent member 14. This significantly reduces the overall height of the conventional package structure 1b, and therefore meeting the requirements for compact and lightweight electronic products.

However, in the conventional package structure 1b, since the conductive pillars 111 are manufactured using the TSV process, and the conductive pillars 111 need to have a certain aspect ratio in order to produce the desired conductive pillars 111, the manufacturing process is relatively challenging and requires a considerable amount of manufacturing time and costs for the chemicals. Thus, it is difficult to lower the manufacturing costs.

Furthermore, the conductive pillars 111 are manufactured by electroplating copper in through holes, but it is difficult to maintain the quality of electroplating as the conductive pillars 111 need to have a certain aspect ratio. For example, the through holes are susceptible to copper depressions or voids, resulting in poor reliability of the conductive pillars 111.

Therefore, there is a need for a solution that addresses the aforementioned issues in the prior art.

### SUMMARY

In view of the aforementioned shortcomings of the prior art, the present disclosure provides an electronic package, which may include: an encapsulating layer having a first surface and a second surface opposite to each other; an electronic component embedded inside the first surface of the encapsulating layer and having a sensing area exposed from the first surface; a circuit layer formed on the encapsulating layer; and at least a conductor formed in the encapsulating layer, interconnecting the first surface and the second surface, electrically connected to the circuit layer, and including a filler and a conductive material surrounding the filler.

The present disclosure further provides a method for manufacturing an electronic package, which may include: providing an encapsulating layer having a first surface and a second surface opposite to each other, at least an electronic component embedded inside the first surface of the encapsulating layer, wherein the electronic component includes a sensing area exposed from the first surface; and forming at least a conductor interconnecting the first surface and the second surface in the encapsulating layer, and forming a circuit layer on the encapsulating layer, such that the at least a conductor is electrically connected with the circuit layer, wherein the at least a conductor includes a filler and a conductive material surrounding the filler.

In an embodiment, the encapsulating layer is made of a molding compound or a primer.

In an embodiment, the first surface of the encapsulating layer is flush with the electronic component.

In an embodiment, the second surface of the encapsulating layer is flush with the electronic component.

In an embodiment, the electronic component is electrically connected with the circuit layer.

In an embodiment, the at least a conductor is formed by: forming in the encapsulating layer at least a through hole interconnecting the first surface and the second surface; forming the conductive material on a wall of the at least a through hole; and forming the filler in the at least a through hole to fill up the at least a through hole.

In an embodiment, the at least a through hole is formed by mechanical drilling.

In an embodiment, the circuit layer is free from being formed on the sensing area.

In an embodiment, an insulating protective layer is further formed on the first surface of the encapsulating layer to cover the circuit layer, and the insulating protective layer includes an opening for exposing the sensing area.

In an embodiment, a transparent member is further provided on the first surface of the encapsulating layer for hooding over the sensing area.

In an embodiment, a circuit structure is further electrically connected with the circuit layer on the second surface of the encapsulating layer.

It can be understood from the above that the electronic package and the method for manufacturing the same according to the present disclosure allow the at least a conductor to be disposed in the encapsulating layer for being electrically connected with the circuit layer. Compared to the conventional TSV technique, the present disclosure is capable of producing through holes of various sizes depending on the required aspect ratios, thereby reducing manufacturing complexity and saving a considerable amount of manufacturing time and costs for the chemicals, and in turn lowering manufacturing costs and increasing throughput.

Furthermore, using mechanical drilling and resin to fill up the through holes in conjunction with the patterning technique (e.g., exposure, developing, etching, resist removal and etc.), quality issues related to through-hole electroplating (copper pillars) in the traditional TSV process can be eliminated. Thus, compared to the prior art, the manufacturing method according to the present disclosure is capable of maintaining the quality of the conductors to improve reliability of the conductors, and lowering the production costs.

In addition, the manufacturing method according to the present disclosure uses the circuit layer (or the circuit structure) in replacement of the conventional package substrate, and uses the conductors in replacement of the conventional wires. Therefore, compared to the traditional package structure by wiring boding, the manufacturing method according to the present disclosure significantly reduces the height of the electronic package, thereby providing ultra-thin and low-cost package structure to meet the needs for compact and lightweight electronic products.

### BRIEF DESCRIPTION OF THE DRAWINGS

FIG. 1A is a cross-sectional view of a conventional package structure;

FIG. 1B is a cross-sectional view of another conventional package structure;

FIGS. 2A to 2E are cross-sectional views illustrating a method for manufacturing a sensing package in accordance with the present disclosure;

FIG. 3A is a cross-sectional view of another embodiment of FIG. 2E;

FIG. 3B is a cross-sectional view of another embodiment of FIG. 3A; and

FIG. 4 is a cross-sectional view of yet another embodiment of FIG. 2E.

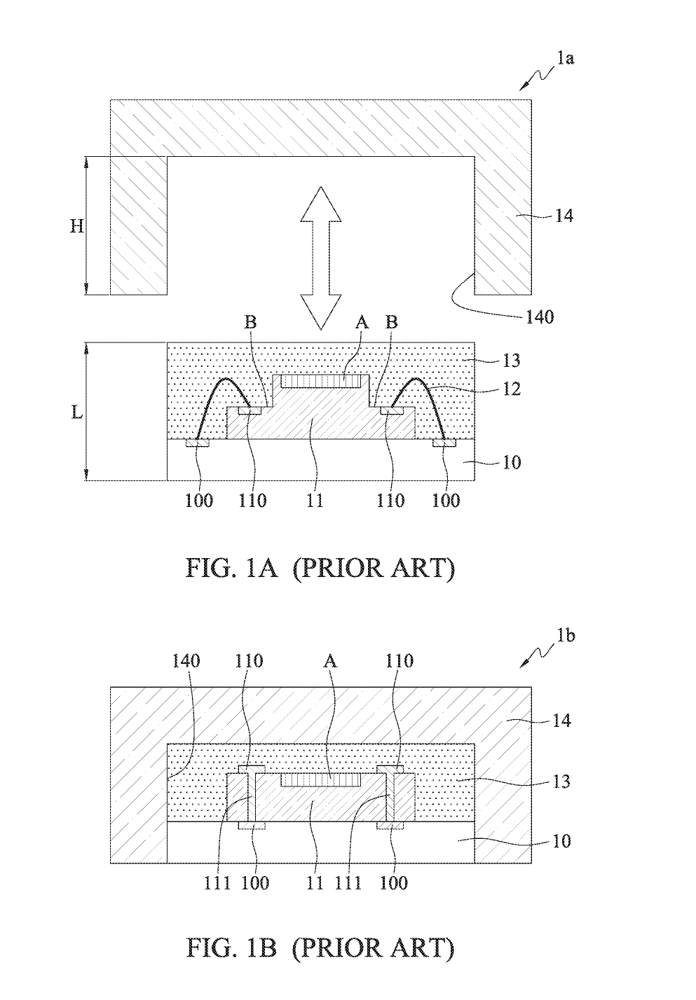

### DETAILED DESCRIPTION OF THE EMBODIMENTS

The technical content of the present disclosure is described by the following embodiments. One with ordinary skill in the art can readily understand the advantages and effects of the present disclosure upon reading the disclosure of this specification. The present disclosure may also be practiced or applied with other different implementations. Based on different contexts and applications, the various details in this specification can be modified and changed without departing from the spirit of the present disclosure.

It should be noted that the structures, ratios, sizes shown in the drawings appended to this specification are to be construed in conjunction with the disclosure of this specification in order to facilitate understanding of those skilled in the art. They are not meant, in any ways, to limit the implementations of the present disclosure, and therefore have no substantial technical meaning. Without affecting the effects created and objectives achieved by the present disclosure, any modifications, changes or adjustments to the structures, ratio relationships or sizes, are to be construed as fall within the range covered by the technical contents disclosed herein. Meanwhile, terms, such as “above”, “first”, “second”, “one”, “a”, “an”, and the like, are for illustrative purposes only, and are not meant to limit the range implementable by the present disclosure. Any changes or adjustments made to their relative relationships, without modifying the substantial technical contents, are also to be construed as within the range implementable by the present disclosure.

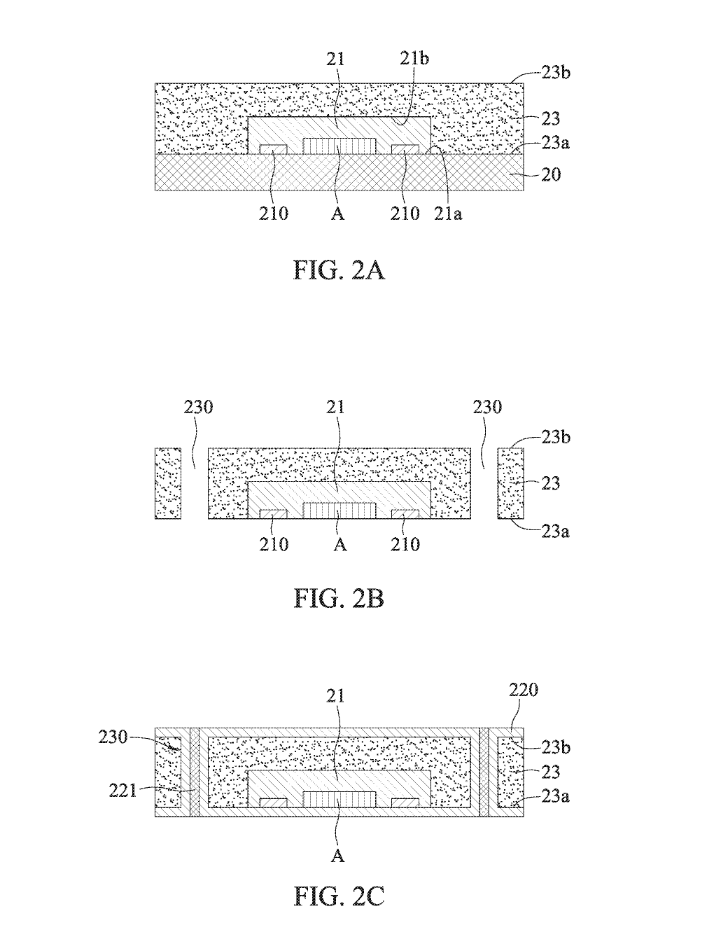

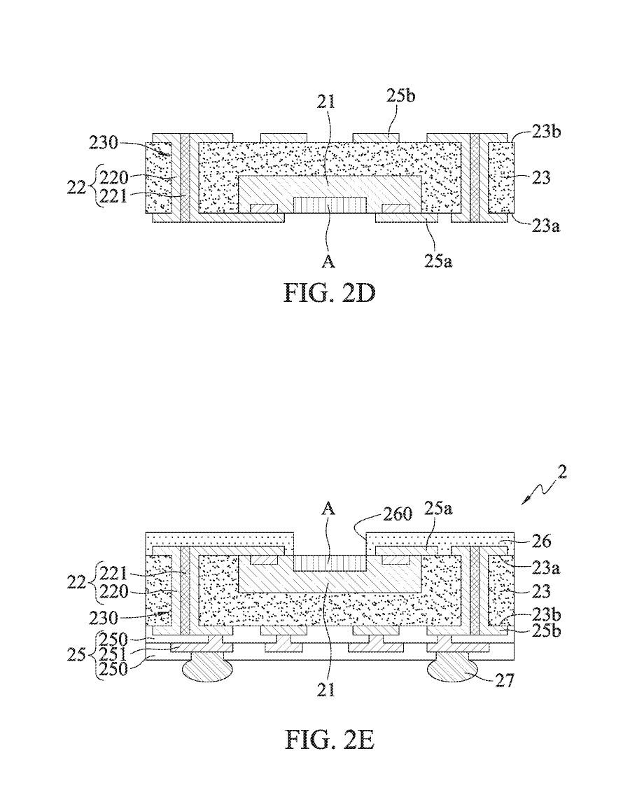

FIGS. 2A to 2E are cross-sectional views illustrating a method for manufacturing a sensing electronic package 2 in accordance with the present disclosure.

As seen in FIG. 2A, at least one electronic component 21 is disposed on a carrier 20, and an encapsulating layer 23 is then formed on the carrier 20 to enclose the electronic component 21.

In an embodiment, the electronic component 21 is a sensing semiconductor chip, such as a sensing chip, for detecting changes in charge, temperature, pressure or the like of an organism, and is preferably a fingerprint recognition chip. The electronic component 21 includes a sensing face 21a and a non-sensing face 21b opposite to each other. The sensing face 21a is combined to the carrier 20, and the sensing face 21a includes a plurality of electrode pads 210 and a sensing area A thereon for receiving signals for biometrics (fingerprint) recognition.

Furthermore, the encapsulating layer 23 includes a first surface 23a and a second surface 23b opposite to each other. The electronic component 21 is embedded in the first surface 23a of the encapsulating layer 23. In an embodiment, the first surface 23a of the encapsulating layer 23 is flush with the sensing face 21a of the electronic component 21.

Moreover, the encapsulating layer 23 can be formed on the carrier 20 by molding, spin coating, lamination etc. The encapsulating layer 23 can be made of a dielectric material, such as epoxy resin. The epoxy resin may further include a molding compound or a primer, such as an epoxy molding compound (EMC), wherein the EMC includes fillers with a ratio of 70 to 90 wt %.

As seen in FIG. 2B, the carrier 20 is removed to expose the first surface 23a of the encapsulating layer 23 and the sensing face 21a of the electronic component 21. Then, a plurality of through holes 230 interconnecting the first surface 23a and the second surface 23b are formed in the encapsulating layer 23.

In an embodiment, the through holes 230 are formed by mechanical drilling.

As seen in FIG. 2C, conductive materials 220 are formed on the first surface 23a and second surface 23b of the encapsulating layer 23, and further extend into the walls of the through holes 230. Thereafter, fillers 221 are formed in the through holes 230 to fill the rest of the space in the through holes 230.

In an embodiment, the conductive materials 220 are copper materials formed by electroplating, and the fillers 221 are made of resin.

As seen in FIG. 2D, the manufacturing process of redistribution layer (RDL) is carried out. In an embodiment, the conductive materials 220 are patterned to form a first circuit layer 25a on the first surface 23a of the encapsulating layer 23 and the sensing face 21a of the electronic component 21, and a second circuit layer 25b on the second surface 23b of the encapsulating layer 23. The conductive materials 220 and the fillers 221 in the through holes 230 form conductors 22 for electrically connecting the first circuit layer 25a with the electrode pads 210 of the electronic component 21, as well as electrically connecting the first circuit layer 25a with the second circuit layer 25b.

In an embodiment, the first circuit layer 25a and the second circuit layer 25b are formed by photolithography (exposure, developing and etching). Preferably, the conductive materials 220 above the sensing area A on the sensing face 21a of the electronic component 21 are removed, such that first circuit layer 25a is not formed on the sensing area A.

As seen in FIG. 2E, an insulating protective layer 26 is formed on the first surface 23a of the encapsulating layer 23 to cover the first circuit layer 25a while exposing the sensing area A from an opening 260 thereof.

In an embodiment, during subsequent processes, a plurality of conductive elements 27, such as solder bumps, are formed on the second circuit layer 25b. A circuit structure 25 can also be formed as needed on the second surface 23b of the encapsulating layer 23 to electrically connect the second circuit layer 25b, and the conductive elements 27 are formed on and electrically connected with the circuit structure 25. The circuit structure 25 includes at least one insulating layer 250 and a circuit portion 251 formed in the insulating layer 250, wherein the circuit portion 251 is electrically connected with the second circuit layer 25b and the conductive elements 27.

Moreover, the insulating layer 250 can be formed on the encapsulating layer 23 by molding, spin coating, lamination etc. The insulating layer 250 can be made of a dielectric material, such as epoxy resin. The epoxy resin may further include a molding compound or a primer, such as an epoxy molding compound (EMC), wherein the EMC includes fillers with a ratio of 70 to 90 wt %. It can be appreciated that the insulating layer 250 and the encapsulating layer 23 can be made of the same or different materials.

There are numerous manufacturing processes regarding the formation of the circuit structure 25, including a build-up process or a RDL process; the present disclosure is not limited as such.

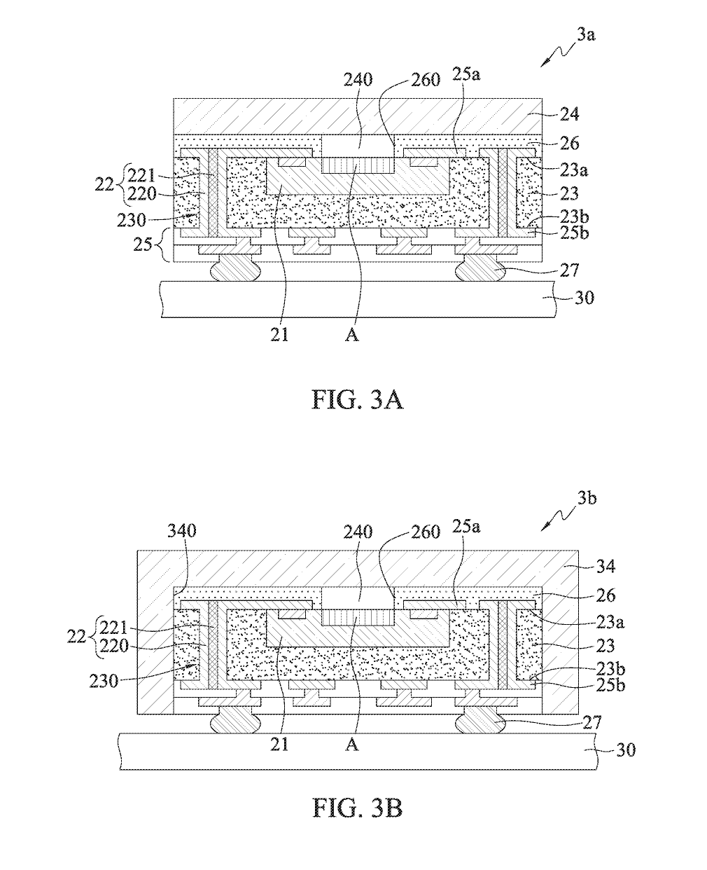

Furthermore, in subsequent processes, as shown by an electronic package 3a of FIG. 3A, a transparent member 24 is disposed on the insulating protective layer 26 on the first surface 23a of the encapsulating layer 23 to hood over the sensing area A, thereby forming a hollow region 240 between the sensing area A and the transparent member 24. As a result, light can pass through the hollow region 240 to arrive at the sensing area A to allow the sensing area A to receive signals for biometrics (fingerprint) recognition. At the other side, the conductive elements 27 are connected to a circuit board 30.

In an embodiment, the transparent member 24 can be a rectangular plate. In another embodiment, as shown by an electronic package 3b of FIG. 3B, a transparent member 34 is an n-shaped structure having an indentation 340 for receiving, for example, the structure shown in FIG. 2E.

The manufacturing method according to the present disclosure employs a “through outside silicon via” (TOSV) technique that allows the conductors 22 for electrically connecting the first circuit layer 25a and the second circuit layer 25b to be formed in the encapsulating layer 23. Compared to the conventional TSV technique, the TOSV technique employed by the present disclosure is capable of producing through holes 230 of various sizes (e.g., small aspect ratio), reducing manufacturing complexity to saving considerable amount of manufacturing time and costs for the chemicals, and in turn lowering manufacturing costs and increasing throughput.

Furthermore, using mechanical drilling and resin to fill up the through holes in conjunction with the patterning technique (e.g., exposure, developing, etching, resist removal and etc.), quality issues (e.g., depressions and voids) related to through-hole electroplating in the traditional TSV process can be eliminated. Thus, compared to the prior art, the manufacturing method according to the present disclosure is capable of maintaining the quality of the conductors 22 to improve reliability of the conductors 22, and lowering the production costs.

In addition, the manufacturing method according to the present disclosure uses the second circuit layer 25b (or the circuit structure 25) in replacement of the conventional package substrate, and uses the conductors 22 in replacement of the conventional wires. Therefore, compared to the traditional package structure by wiring boding, the manufacturing method according to the present disclosure significantly reduces the height of the electronic package 2, 3a, 3b, thereby providing ultra-thin and low-cost package structure to meet the needs for compact and lightweight electronic products.

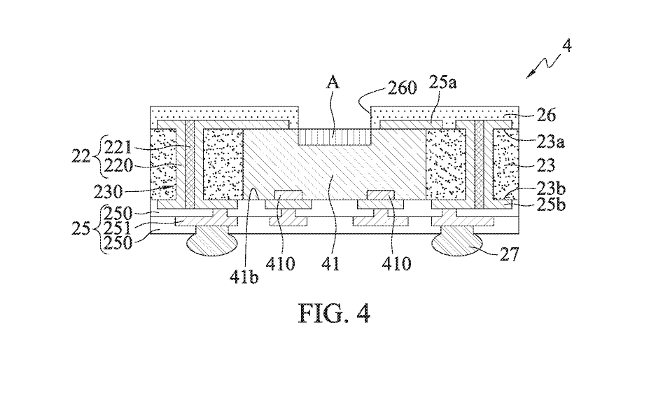

In addition, it can be appreciated that electrode pads 410 of an electronic component 41 can be disposed on the non-sensing face 41b as shown in an electronic package 4 of FIG. 4, and the second surface 23b of the encapsulating layer 23 is flush with the non-sensing face 41b.

The present disclosure includes an electronic package 2, 3a, 3b, 4, which includes: an encapsulating layer 23, an electronic component 21, a first circuit layer 25a, a second circuit layer 25b, and a plurality of conductors 22.

The encapsulating layer 23 includes a first surface 23a and a second surface 23b opposite to each other.

The electronic component 21 is embedded at the first surface 23a of the encapsulating layer 23, and includes a sensing area A exposed from the first surface 23a.

The first circuit layer 25a is formed on the first surface 23a of the encapsulating layer 23.

The second circuit layer 25b is formed on the second surface 23b of the encapsulating layer 23.

The conductors 22 are formed in the encapsulating layer 23, interconnect the first surface 23a and the second surface 23b, electrically connect the first circuit layer 25a with the second circuit layer 25b, and include fillers 221 and conductive materials 220 surrounding the fillers 221.

In an embodiment, the encapsulating layer 23 is made of a molding compound or a primer.

In an embodiment, the first surface 23a of the encapsulating layer 23 is flush with the electronic component 21.

In an embodiment, the second surface 23b of the encapsulating layer 23 is flush with the electronic component 21.

In an embodiment, the electronic component 21 is a sensing semiconductor chip.

In an embodiment, the electronic component 21 is electrically connected with the first circuit layer 25a or the second circuit layer 25b.

In an embodiment, through holes 230 interconnecting the first surface 23a and the second surface 23b are formed in the encapsulating layer 23, the conductive materials 220 are formed on the walls of the through holes 230, and the fillers 221 are formed in the through holes 230 to fill up the through holes 230.

In an embodiment, the first circuit layer 25a is not formed on the sensing area A.

In an embodiment, the electronic package 2, 3a, 3b, 4 further includes an insulating protective layer 26 formed on the first surface 23a of the encapsulating layer 23 to cover the first circuit layer 25a while exposing the sensing area A through an opening 260 thereof.

In an embodiment, the electronic package 3a, 3b further includes a transparent member 24, 34 disposed on the first surface 23a of the encapsulating layer 23 to hood over the sensing area A.

In an embodiment, the electronic package 2, 3a, 3b, 4 further includes a circuit structure 25 formed on the second surface 23b of the encapsulating layer 23, and the circuit structure 25 is electrically connected with the second circuit layer 25b.

In conclusion, the electronic package and the method for manufacturing the same according to the present disclosure include providing conductors in the encapsulating layer for electrically connecting the first circuit layer and the second circuit layer, thereby reducing manufacturing complexity and manufacturing costs and increasing throughput, while maintaining the quality of the conductors to improve the reliability of the conductors.

Furthermore, in the present disclosure, the second circuit layer (or the circuit structure) is used instead of the traditional package substrate, and the conductors are used instead of the conventional wires so as to significantly reduce the height of the electronic package, thereby achieving results that meet the needs for compact and lightweight electronic products.

The above embodiments are only used to illustrate the principles of the present disclosure, and should not be construed as to limit the present disclosure in any way. The above embodiments can be modified by those with ordinary skill in the art without departing from the scope of the present disclosure as defined in the following appended claims.

What is claimed is:

1. An electronic package, comprising:
an encapsulating layer having a first surface and a second surface opposite to each other;
an electronic component embedded inside the first surface of the encapsulating layer and including a sensing area exposed from the first surface;
a circuit layer formed on the encapsulating layer; and
at least a conductor formed in the encapsulating layer, interconnecting the first surface and the second surface, electrically connected to the circuit layer, and having a filler and a conductive material surrounding the filler.

2. The electronic package of claim 1, wherein the encapsulating layer is made of a molding compound or a primer.

3. The electronic package of claim 1, wherein at least one of the first surface and the second surface of the encapsulating layer is flush with the electronic component.

4. The electronic package of claim 1, wherein the electronic component is electrically connected with the circuit layer.

5. The electronic package of claim 1, further comprising at least a through hole formed in the encapsulating layer interconnecting the first surface and the second surface, wherein the conductive material is formed on a wall of the at least a through hole, and the filler is formed in and fills up the at least a through hole.

6. The electronic package of claim 1, wherein the circuit layer is free from being formed on the sensing area.

7. The electronic package of claim 1, wherein the circuit layer is formed on the first surface of the encapsulating layer, the electronic package further comprises an insulating protective layer formed on the first surface of the encapsulating layer and covering the circuit layer, and the insulating protective layer includes an opening for exposing the sensing area.

8. The electronic package of claim 1, further comprising a transparent member disposed on the first surface of the encapsulating layer and hooding over the sensing area.

9. The electronic package of claim 1, further comprising a circuit structure electrically connected with the circuit layer formed on the second surface of the encapsulating layer.

10. A method for manufacturing an electronic package, comprising:
providing an encapsulating layer including a first surface and a second surface opposite to each other, and embedding inside the first surface of the encapsulating layer at least an electronic component including a sensing area exposed from the first surface; and
forming at least a conductor interconnecting the first surface and the second surface in the encapsulating layer, and forming on the encapsulating layer a circuit layer electrically connected to the at least a conductor including a filler and a conductive material surrounding the filler.

11. The method claim 10, wherein the encapsulating layer is made of a molding compound or a primer.

12. The method of claim 10, wherein at least one of the first surface and the second surface of the encapsulating layer is flush with the electronic component.

13. The method of claim 10, wherein the electronic component is electrically connected with the circuit layer.

14. The method of claim 10, wherein forming the at least a conductor includes:
forming in the encapsulating layer at least a through hole interconnecting the first surface and the second surface;
forming the conductive material on a wall of the at least a through hole; and
forming the filler in the at least a through hole to fill up the at least a through hole.

15. The method of claim 14, wherein the at least a through hole is formed by mechanical drilling.

16. The method of claim 10, wherein the circuit layer is free from being formed on the sensing area.

17. The method of claim 10, wherein the circuit layer is formed on the first surface of the encapsulating layer.

18. The method of claim 17, further comprising forming an insulating protective layer on the first surface of the encapsulating layer to cover the circuit layer, wherein the insulating protective layer includes an opening for exposing the sensing area.

19. The method of claim 10, further comprising providing on the first surface of the encapsulating layer a transparent member hooding over the sensing area.

20. The method of claim 10, further comprising forming a circuit structure electrically connected with the circuit layer on the second surface of the encapsulating layer.
